(19) United States
(12) Patent Application Publication
(10) Pub. No.: US 2021/0336139 A1
(43) Pub. Date: Oct. 28, 2021

(54) PEROVSKITE FILM AND METHOD OF MANUFACTURING SAME

(71) Applicant: SHENZHEN CHINA STAR OPTOELECTRONICS SEMICONDUCTOR DISPLAY TECHNOLOGY CO., LTD., Shenzhen (CN)

(72) Inventors: Miao DUAN, Shenzhen (CN); Chiayu LEE, Shenzhen (CN); Chunche HSU, Shenzhen (CN); Shujhih CHEN, Shenzhen (CN); Bo HE, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/616,985

(22) PCT Filed: Aug. 28, 2019
(86) PCT No.: PCT/CN2019/102939

§ 371 Date: Nov. 26, 2019

(30) Foreign Application Priority Data
Jun. 28, 2019 (CN) 201910571558.8

(51) Int. Cl. H01L 51/00; B05D 1/42; B05D 3/02; B05D 5/00

(52) U.S. Cl. CPC H01L 51/0003; B05D 1/42; H01L 51/5012; B05D 3/0272; B05D 5/00; B05D 3/0218

(57) ABSTRACT

A perovskite film and a method of manufacturing same are provided. By adding a surfactant during a process of manufacturing a perovskite solution and adopting a coating method during a process coating the perovskite solution onto a substrate, a flatness of the perovskite film is effectively improved, and a thickness of the perovskite film is uniform. Therefore, the perovskite film becomes more smoothly and has better compactness. Thus, the present invention also has advantages of simple manufacturing process, reduced cost, and suitable for large-scale industrial production.

### FIELD OF INVENTION

The present invention relates to a field of display, and more particularly, relates to a perovskite film and a method of manufacturing same.

### BACKGROUND OF INVENTION

The most frequently used elements in electroluminescent perovskite devices include a substrate, a transparent electrode, a hole transport layer, a perovskite film layer, an electron transport layer, and a metal electrode. The perovskite film layer is a perovskite light-emitting layer.

In the prior art, organic-inorganic lead halide perovskites are used as novel and excellent semiconductor material in the field of optoelectronic devices. On one hand, perovskite materials have many advantages such as ability to be formulated in a solution without high-temperature heating process, and capable of adjusting its optical band gap by changing elemental compositions of the perovskite material to emit different colors. On the other hand, the perovskite material can emit strong fluorescence, which makes it become a potential material of electroluminescent devices and a crucial role of the display field.

Currently, luminous efficiency of perovskite light-emitting diodes (LEDs) is increasingly improved. Maximum external quantum efficiency (EQE) of green light-emitting electroluminescent perovskite devices, red light-emitting electroluminescent perovskite devices, and near-infrared electroluminescent perovskite devices have exceeded 20%. In other words, the perovskite LEDs have made a big step forward in industrialization.

In the prior art, perovskite electroluminescent layers are manufactured by a spin coating process. Specifically, dropping perovskite solution on a substrate, dry the excess perovskite solution by high-speed rotation of a spin coater, then annealing the perovskite solution to form a perovskite film. The spin coating process is only suitable for manufacturing small-size electroluminescent devices (generally 2 cm*2 cm). The smaller the electroluminescent device is, the smaller a substrate of the electroluminescent device is. The larger the electroluminescent device is, the larger the substrate of the electroluminescent device is. However, the substrate is prone to detach from a plate of a spin coater during high-speed rotation if the substrate is too large, which is not beneficial to form a film and cannot satisfy requirement of industrialization. In addition, the perovskite film made by the spin coating process has an uneven thickness and a poor flatness.

### SUMMARY OF INVENTION

An object of the present invention is to provide a perovskite film and a method of manufacturing same, which solve technical problems that conventional perovskite films have an uneven thickness, a poor flatness, and cannot satisfy requirement of industrialization.

To achieve the above object, the present invention provides a method of manufacturing a perovskite film comprising steps of: adding a precursor solution and a surfactant into a vessel to obtain a perovskite solution, coating the perovskite solution onto a substrate; and heating and drying the substrate to obtain a perovskite film.

Furthermore, the perovskite solution and the substrate are preheated before the coating step.

Furthermore, the perovskite solution and the substrate are preheated to 30 to 60 degrees Celsius.

Furthermore, a molar ratio of the precursor solution to the surfactant ranges from 1:2000 to 1:4000.

Furthermore, the precursor solution comprises one or more of a green light-emitting perovskite composition, a red light-emitting perovskite composition, and a blue light-emitting perovskite composition, wherein the surfactant comprises lecithin.

Furthermore, the perovskite solution is coated onto the substrate by a scraper, and a moving speed of the scraper ranges from 55 mm/s to 65 mm/s.

Furthermore, the heating and drying steps further comprise the following steps: heating the substrate on a heating platform; and drying the substrate in a vacuum drying oven.

Furthermore, the substrate is heated to 58 to 62 degrees Celsius for 5 to 10 minutes in the heating step, and the substrate is dried under vacuum for 15 to 30 minutes in the drying step.

To achieve the above object, the present invention further provides a perovskite film which is manufactured by the above method.

Regarding the beneficial effects of the present invention, a perovskite film and a method of manufacturing same are provided. By adding a surfactant during a process of manufacturing a perovskite solution and adopting a coating method during a process coating the perovskite solution onto a substrate, a flatness of the perovskite film is effectively improved, and a thickness of the perovskite film is uniform. Therefore, the perovskite film becomes more smoothly and has better compactness. Thus, the present invention also has advantages of simple manufacturing process, reduced cost, and suitable for large-scale industrial production.

### DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which figures those skilled in the art can derive further figures without making any inventive efforts.

FIG. 1 is a flowchart showing a method of manufacturing a perovskite film according to the present invention.

FIG. 2 is a flowchart showing a step of heating and drying the substrate.

FIG. 3 is a schematic structural diagram of electroluminescent device.

### DETAILED DESCRIPTION OF PREFERRED EMBODIMENTS

Hereinafter a preferred embodiment of the present invention will be described with reference to the accompanying drawings to exemplify the embodiments of the present invention can be implemented, which can fully describe the technical contents of the present invention to make the technical content of the present invention clearer and easy to understand. However, the described embodiments are only some of the embodiments of the present invention, but not all of the embodiments. All other embodiments obtained by those skilled in the art based on the embodiments of the present invention without creative efforts are within the scope of the present invention.

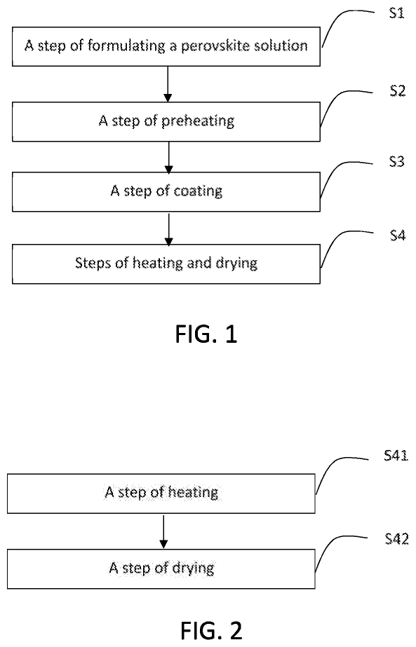

As shown in FIG. 1, the present embodiment provides a method of manufacturing a perovskite film. The method includes step 1 to step 4.

Step 1 is a step of preparing a perovskite solution: adding a precursor solution and a surfactant into a vessel to obtain a perovskite solution.

During the step of preparing a perovskite solution, a molar ratio of the precursor solution to the surfactant ranges from 1:2000 to 1:4000. The precursor solution includes one or more of a green light-emitting perovskite composition such as CH₃NH₃PbBr₃ and CsPbBr₃, a red light-emitting perovskite composition such as CH₃NH₃Pb(Br/I)₃ and CsPb(Br/I)₃, and a blue light-emitting perovskite composition such as CH₃NH₃Pb(Br/Cl)₃ and CsPb(Br/Cl)₃. The surfactant includes lecithin which is beneficial to form a uniform perovskite film and improve a flatness of the perovskite film in the follow-up process of the perovskite solution.

Step 2 is a step of preheating: preheating the perovskite solution and a substrate.

Preheating the perovskite solution and the substrate on a platform to 30 to 60 degrees Celsius. In the present embodiment, preferred temperature is 48, 50, and 52 degrees Celsius. An object of heating the perovskite solution is to fully dissolve the precursor solution, and increase a reaction rate between the precursor solution and the surfactant. An object of heating the substrate is to make a temperature of the substrate consistent with a temperature of the perovskite solution, thereby preventing solute of the perovskite solution from precipitation because of temperature changes.

Step 3 is a step of coating: coating the perovskite solution onto the substrate.

Coating the perovskite solution onto the substrate by a scraper having a smooth surface. The scraper is moving along a fixed direction with a fixed moving speed, and the moving speed of the scraper ranges from 55 mm/s to 65 mm/s. A preferred moving speed of the scraper is 60 mm/s. On one hand, force applied to the scraper is uniform, so that the perovskite solution is uniformly coated on the substrate, thereby making a thickness of the film layer uniform. On the other hand, a crystallization effect of the perovskite solution coated on the substrate is improved. Therefore, when the fixed moving speed of the scraper is too fast, defects such as the perovskite solution distributed on the substrate is not uniform and a thickness of the film is not uniform are prevented.

Step 4 is a step of heating and drying: heating and drying the substrate to obtain the perovskite film.

As shown in FIG. 2, step 4 further includes step 41 and step 42.

Step 41 is a step of heating: heating the substrate on the platform.

Specifically, the substrate is preheated to 58 to 62 degrees Celsius for 5 to 10 minutes. In the present embodiment, a preferred temperature of the substrate is 60 degrees Celsius. The perovskite solution is gradually condensed on a surface of the substrate. If the temperature of the substrate is too high, the crystallization rate of the perovskite solution will be too fast. As a result, sizes of crystals will not be uniform, thereby badly affecting the flatness and compactness of the perovskite film. On the other hand, if the temperature of the substrate is too low, the crystallization rate of the perovskite solution will not be uniform, which will also cause uneven sizes of crystals, which badly affects the flatness and compactness of the perovskite film. In summary, in the present embodiment, the preferred temperature of the substrate is 60 degrees Celsius, which is beneficial to obtain a dense and smooth perovskite film with a uniform size.

Step 42 is a step of drying: drying the substrate in a 100 degrees Celsius vacuum drying oven for 15 to 30 minutes. After that, the moisture remaining in the perovskite film will be completely evaporated, thereby obtaining a dense and smooth perovskite film with a uniform size.

The method of manufacturing a perovskite film is provided by the present embodiment. By adding a surfactant during a process of manufacturing a perovskite solution and adopting a coating method during a process of coating the perovskite solution onto a substrate, a dense and smooth perovskite film with a uniform size can be obtained. Furthermore, the method provided by the present embodiment can also be applied to large-scale industrial production.

The perovskite film can be applied to an electroluminescent device which will be described below.

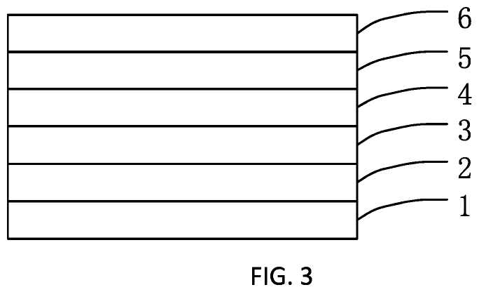

As shown in FIG. 3, an electroluminescent device includes a substrate 1, a first electrode 2, a hole transport layer 3, a perovskite film 4, an electron transport layer 5, and a second electrode 6 which are sequentially disposed on each other.

Material of the substrate 1 includes but not limited to at least one of a glass substrate and a polyethylene terephthalate (PET) substrate.

The first electrode 2 is disposed on a top surface of the substrate 1, and the first electrode 2 is a transparent electrode (cathode). Material of the first electrode 2 includes but not limited to at least one of indium tin oxide (ITO), fluorine tin oxide (FTC), and graphene. Process of obtaining the first electrode 2: using ultrasonic cleaning to sequentially wash the material of the first electrode 2 by detergent, deionized water, and absolute ethanol for 15 minutes respectively; blow-drying the material of the first electrode 2 with nitrogen, and then immediately treating the material of the first electrode with ultraviolet ozone in an ultraviolet ozone (UVO) device for 10 minutes.

The hole transport layer 3 is disposed on a top surface of the first electrode 2. Process of obtaining the hole transport layer 3: coating poly(3,4-ethylenedioxythiophene):poly(styrenesulfonate) (PEDOT:PSS) solution on the top surface of the first electrode 2 by a spin coating process at 2000 rpm, and then annealing the PEDOT:PSS solution to obtain the hole transport layer 3. A thickness of the hole transport layer 3 is about 30 nm.

The perovskite film 4 is disposed on a surface of the hole transport layer 3. The perovskite film 4 includes a green light-emitting perovskite composition such as CH₃NH₃PbBr₃ and CsPbBr₃, a red light-emitting perovskite composition such as CH₃NH₃Pb(Br/I)₃ and CsPb(Br/I)₃, and a blue light-emitting perovskite composition such as CH₃NH₃Pb(Br/Cl)₃ and CsPb(Br/Cl)₃. The perovskite film 4 has a uniform thickness, a high flatness, and good compactness, which can be applied to large-scale industrial production.

The electron transport layer 5 is disposed on a surface of the perovskite film 4. Preferably, material of the transport layer is 2,2′,2″-(1,3,5-Benzinetriyl)-tris(1-phenyl-1-H-benzimidazole) (TPBi).

The second electrode 6 (anode) is disposed on a top surface of the electron transport layer 5. Preferably, material of the second electrode 6 includes molybdenum oxide and silver.

A perovskite film and a method of manufacturing same are provided by the present embodiment. By adding a surfactant during a process of manufacturing a perovskite solution and adopting a coating method during a process coating the perovskite solution onto a substrate, a flatness of the perovskite film is effectively improved, and a thickness of the perovskite film is uniform. Therefore, the perovskite film becomes more smoothly and has better compactness. Thus, the present invention also has advantages of simple manufacturing process, reduced cost, and suitable for large-scale industrial production.

The present disclosure has been described with a preferred embodiment thereof. The preferred embodiment is not intended to limit the present disclosure, and it is understood that many changes and modifications to the described embodiment can be carried out without departing from the scope and the spirit of the disclosure that is intended to be limited only by the appended claims.

What is claimed is:

1. A method of manufacturing a perovskite film, comprising steps of:
preparing a perovskite solution: adding a precursor solution and a surfactant into a vessel to obtain a perovskite solution;
coating the perovskite solution onto a substrate; and
heating and drying the substrate to obtain a perovskite film.

2. The method of claim 1, wherein the perovskite solution and the substrate are preheated before the coating step.

3. The method of claim 2, wherein the perovskite solution and the substrate are preheated to 30 to 60 degrees Celsius.

4. The method of claim 1, wherein a molar ratio of the precursor solution to the surfactant ranges from 1:2000 to 1:4000.

5. The method of claim 1, wherein the precursor solution comprises one or more of a green light-emitting perovskite composition, a red light-emitting perovskite composition, and a blue light-emitting perovskite composition; and
wherein the surfactant comprises lecithin.

6. The method of claim 1, wherein the perovskite solution is coated onto the substrate by a scraper, and a moving speed of the scraper ranges from 55 mm/s to 65 mm/s.

7. The method of claim 1, wherein the heating and drying steps further comprise the following steps:
heating the substrate on a heating platform; and
drying the substrate in a vacuum drying oven.

8. The method of claim 7, wherein the substrate is heated to 58 to 62 degrees Celsius for 5 to 10 minutes in the heating step; and
wherein the substrate is dried under vacuum for 15 to 30 minutes in the drying step.

9. A perovskite film, wherein the perovskite film is manufactured by the method of claim 1.
